(19) United States
(12) Patent Application Publication
(10) Pub. No.: US 2022/0208518 A1
(43) Pub. Date: Jun. 30, 2022

(54) Directly Driven Hybrid ICP-CCP Plasma Source

(71) Applicants: Mattson Technology, Inc., Fremont, CA (US); Beijing E-Town Semiconductor Technology Co., Ltd., Beijing (CN)

(72) Inventor: Maolin Long, Santa Clara, CA (US)

(21) Appl. No.: 17/551,244

(22) Filed: Dec. 15, 2021

Related U.S. Application Data
(60) Provisional application No. 63/210,624, filed on Jun. 15, 2021.
(60) Provisional application No. 63/130,985, filed on Dec. 28, 2020.

(51) Int. Cl. H01J 37/32; H01L 21/263

(52) U.S. Cl. CPC H01J 37/32155; H01L 21/263; H01J 37/32091; H01J 37/321

(57) ABSTRACT

Systems and methods for processing a workpiece are provided. In one example implementation, a method for processing a workpiece can include supporting a workpiece on a workpiece support. The method can include processing the workpiece by exposing the workpiece to one or more radicals generated using a hybrid plasma source. In one embodiment, the plasma source comprises a resonant circuit that that includes an inductively coupled plasma source and a capacitively coupled plasma source. A controller can be configured to adjust the excitation frequency of the resonant circuit by reducing a harmonic current below a target value, wherein the harmonic current is a sum of one or more currents respectively corresponding to one or more harmonics of the excitation frequency.

### PRIORITY CLAIM

The present application claims priority to U.S. Provisional Patent Application Ser. No. 63/130,985, filed Dec. 28, 2020, which is incorporated herein by reference. The present application claims priority to U.S. Provisional Application Ser. No. 63/210,624, titled “Directly Driven Hybrid ICP-CCP Plasma Source,” filed on Jun. 15, 2021, which is incorporated herein by reference.

### FIELD

The present disclosure relates generally to apparatus, systems, and methods for plasma processing of a workpiece. More particularly, a direct drive power generation system can be incorporated into a hybrid plasma source and/or a plasma processing apparatus for processing a substrate using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive coupling, etc.) are often used for plasma processing to produce high density plasma and reactive species for processing substrates. In plasma dry strip processes, neutral species (e.g., radicals) from a plasma generated in a remote plasma chamber pass through a separation grid into a processing chamber to treat a workpiece, such as a semiconductor wafer. In plasma etch processes, radicals, ions, and other species generated in a plasma directly exposed to the workpiece can be used to etch and/or remove a material on a workpiece.

### SUMMARY

Aspects and advantages of embodiments of the present disclosure will be set forth in part in the following description, or may be learned from the description, or may be learned through practice of the embodiments.

One example aspect of the present disclosure is directed to a directly driven hybrid plasma source comprising an inductively coupled plasma (ICP) source, a capacitively coupled plasma (CCP) source, and a controller. The controller is configured to control operation of the inductively coupled plasma source and the capacitively coupled plasma source such that the inductively coupled plasma source and the capacitively coupled plasma source form a resonant circuit.

Another example aspect of the present disclosure is directed to a method for processing a workpiece. The method includes exciting a plasma source at an excitation frequency to expose the workpiece to one or more radicals generated by the plasma source. The excitation frequency is controlled by reducing a harmonic current below a target value, wherein the harmonic current is a sum of one or more currents respectively corresponding to one or more harmonics of the excitation frequency.

Yet another example aspect of the present disclosure is directed to an apparatus for processing a workpiece. The apparatus includes a processing chamber having an interior space operable to receive a process gas. The apparatus includes a substrate holder in the interior space of the processing chamber operable to hold a substrate. The apparatus includes a hybrid plasma source including a resonant circuit that includes an inductively coupled plasma source and a capacitively coupled plasma source, the resonant circuit configured for operation at an excitation frequency. The apparatus also includes a controller configured to adjust the excitation frequency by reducing a harmonic current below a target value, wherein the harmonic current is a sum of one or more currents respectively corresponding to one or more harmonics of the excitation frequency.

Variations and modifications can be made to these example embodiments of the present disclosure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus according to example embodiments of the present disclosure;

FIG. 2 depicts example injection of a gas using post-plasma injection according to example embodiments of the present disclosure;

FIG. 3A depicts an example plasma processing apparatus according to example embodiments of the present disclosure comprising a hybrid ICP-CCP source driven by a single half-bridge direct drive RF unit;

FIG. 3B depicts an example plasma processing apparatus according to example embodiments of the present disclosure in which an ICP source, CCP source, and RF bias are all driven by one single direct drive generator;

FIG. 4A depicts an example plasma processing apparatus according to example embodiments of the present disclosure comprising variable capacitors to adjust operating frequency and uniformity;

FIG. 4B depicts a lumped parameter model circuit diagram for the example shown in FIG. 4A;

FIG. 5A depicts an example plasma processing apparatus according to example embodiments of the present disclosure comprising an ICP source, CCP source, and RF bias components with variable tuning capacitors.

FIG. 5B depicts a lumped parameter model circuit diagram for the example shown in FIG. 5A;

FIG. 6 depicts an example plasma processing apparatus according to example embodiments of the present disclosure comprising a single H-bridge direct drive generator to power an ICP source, CCP source, and RF bias;

FIG. 7 depicts a flow diagram of an example method of processing a workpiece; and

FIG. 8 depicts a flow diagram of an example method of frequency tuning for a directly driven hybrid ICP-CCP plasma source.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

Example aspects of the present disclosure are directed to a directly-driven hybrid inductively coupled plasma (ICP) and capacitively coupled plasma (CCP) source. In some embodiments, a direct drive RF generator can drive a plasma source without the need for an impedance matching network. The RF operating frequency of the direct drive generator can be adjustably tuned to effect increased and/or maximum power transfer to the plasma source.

Existing direct drive generator designs can be used for either ICP source or CCP source, but in either case, an external reactive component has generally been required to form a series resonance with the ICP source or the CCP source at the operating generator frequency—i.e., to form a tank circuit. Given that maximal power transfer occurs at or near resonance of the tank circuit, when operating conditions in the plasma chamber change, the operating generator frequency is tuned automatically to track the chamber condition changes, to re-establish the series resonance.

These prior designs suffer from several disadvantages. Because the RF generators directly couple to the plasma source via an additional reactive component in series with the plasma source, these external reactive components consume RF power that is not used to create plasma, which is inefficient.

Furthermore, tracking the chamber condition has presented several challenges. In some prior examples, whether the tank circuit is operating in series resonance or not is detected by the VI probe at the output of the direct drive generator. When the phase angle between the measured voltage and the measured current is zero degrees, series resonance is achieved. When the phase angle is not zero, the frequency will be tuned up or down to force the phase angle to zero. The phase angle measurement accuracy must be within 0.1 degrees or less. It is not trivial to measure the phase angle accurately before the frequency is tuned into series resonance, because there are harmonics in the RF current and there are also harmonics and oscillation in voltage. In an ideal case, the voltage at the measurement location should be a square waveform. But due to all the strays in the DC rail voltage supply delivery path and the coupling from the RF power at its load, the voltage waveform at the measurement location is generally not a clean square waveform.

In other prior examples, the detection for the series resonance is not done by checking the phase angle, but instead by tracking the magnitude of the RF current at the fundamental frequency (i.e., the operating generator frequency). When the fundamental RF current is at its maximum, series resonance is achieved. But the RF current at fundamental can still be noisy depending on the Q value of the whole system. With chamber conditions that have lower Q values, the tank circuit would not be able to completely filter out all the harmonics, which confuses the RF current maximum detection and makes the tracking of the RF current maximum difficult, yielding a system that can fail to accurately track the chamber condition and end up operating at a sub-optimal operating generator frequency.

Advantageously, embodiments of the direct drive RF generator according to example embodiments of the present disclosure resolve these and other deficiencies of such prior direct drive RF generators. Unlike the existing direct drive RF technology, embodiments of the present disclosure use the capacitance of a CCP source and the inductance of an ICP source to directly form a tank circuit. With the plasma sources themselves forming the tank circuit, the plasma sources can be driven to resonance (i.e., at an optimally efficient frequency) without requiring any non-plasma-producing reactive components—or using components with less reactance—reducing system inefficiencies.

Of additional advantage, embodiments of the present disclosure provide for improved control of the resonant condition of a plasma source or sources by controlling the operating generator frequency based on the minimization and/or reduction of the current of the harmonics of the fundamental (i.e., the operating generator frequency). When the sum of the RF current of all the harmonic components is driven to its minimum by tuning the operating generator frequency, series resonance is achieved.

Of additional advantage, variable capacitors placed in parallel with one or both of the ICP source and the CCP source can be used to adjust the amount of RF power respectively deposited into the ICP source and CCP source to tune the plasma density uniformity from center to edge.

Embodiments of the present disclosure can be implemented with RF generators employing full or half bridge (e.g., H-bridge) switching designs. It is to be understood by persons of ordinary skill in the art that embodiments of the present disclosure are readily implementable using a number of different RF pulsing schemes with almost unlimited levels of RF pulsing.

Embodiments of the present disclosure that include improved direct drive RF power generation for driving a plasma source can yield corresponding improvements in particular plasma processing applications. For example, in plasma processing applications, new process applications in nitridation and/or integrated nitridation and anneal require hardware capability of pulsed RF plasma. As such, technical enhancements afforded by aspects of the disclosed technology can yield improved plasma processing applications with pulsed RF plasma.

Accordingly, aspects of the present disclosure provide a number of technical effects and benefits. Furthermore, embodiments of the present disclosure reduce the cost of RF hardware by requiring fewer components and enabling more efficient operation.

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece. A “remote plasma” refers to a plasma generated remotely from a workpiece, such as in a plasma chamber separated from a workpiece by a separation grid. A “direct plasma” refers to a plasma that is directly exposed to a workpiece, such as a plasma generated in a processing chamber having a pedestal operable to support the workpiece.

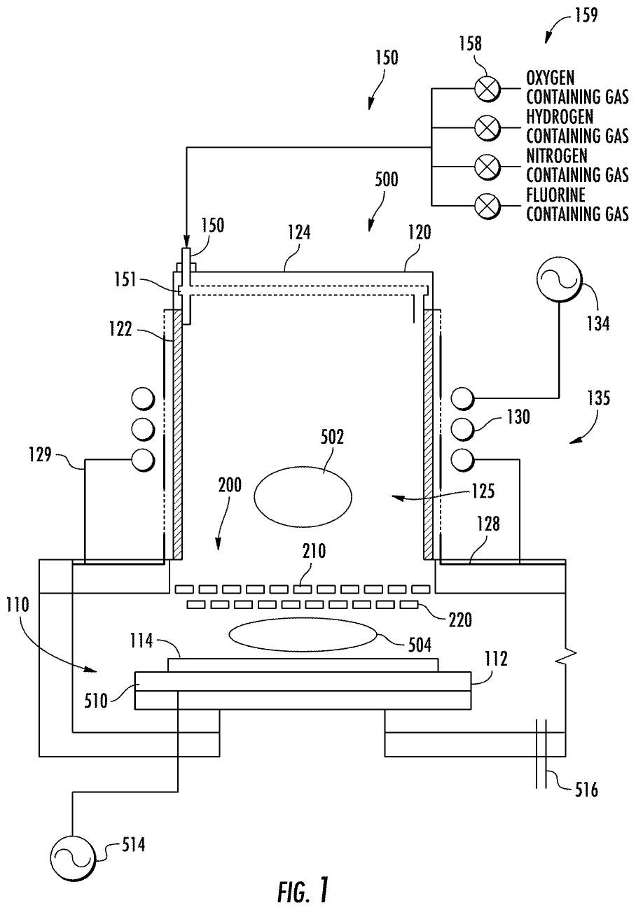

FIG. 1 depicts an example plasma processing apparatus 500 that can be used to implement processes according to example embodiments of the present disclosure. The plasma processing apparatus includes a processing chamber 110 and a plasma chamber 120 that is separated from the processing chamber 110. Processing chamber 110 includes a workpiece holder or pedestal 112 operable to hold a workpiece 114 to be processed, such as a semiconductor wafer. In this example illustration, a plasma 502 is generated in plasma chamber 120 (i.e., plasma generation region) by an inductively coupled plasma source 135 and desired species are channeled from the plasma chamber 120 to the surface of workpiece 114 through a separation grid assembly 200.

The plasma chamber 120 includes a dielectric side wall 122 and a ceiling 124. The dielectric side wall 122, ceiling 124, and separation grid 200 define a plasma chamber interior 125. In some embodiments, dielectric side wall 122 can be formed from a dielectric material, such as quartz and/or alumina. In some embodiments, dielectric side wall 122 can be formed from a ceramic material. The inductively coupled plasma source 135 can include an induction coil 130 disposed adjacent the dielectric side wall 122 about the plasma chamber 120. One end of the induction coil 130 is directly coupled to an RF power generator terminal 134. The other end of the induction coil 130 is electrically coupled to an electrode 128 via a conductive coupling 129.

Process gases (e.g., an inert gas) can be provided to the chamber interior from gas supply 150 and annular gas distribution channel 151 or other suitable gas introduction mechanism. When the induction coil 130 is energized with RF power from the RF power generator terminal 134, a plasma 502 can be generated in the plasma chamber 120. In a particular embodiment, the plasma processing apparatus 500 can include an optional grounded Faraday shield around the plasma chamber 120 to reduce capacitive coupling of the induction coil 130 to the plasma 502.

As shown in FIG. 1, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

For instance, separation grid assembly 200 can be used to filter ions generated by the plasma. The separation grid 200 can have a plurality of holes. Charged particles (e.g., ions) can recombine on the walls in their path through the plurality of holes. Neutral species (e.g. radicals) can pass through the holes.

In some embodiments, the separation grid 200 can be configured to filter ions with an efficiency greater than or equal to about 90%, such as greater than or equal to about 95%. A percentage efficiency for ion filtering refers to the number of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the separation grid 200 can be a multi-plate separation grid. The multi-plate separation grid can have multiple separation grid plates in parallel. The arrangement and alignment of holes in the grid plate can be selected to provide a desired efficiency for ion filtering, such as greater than or equal to about 95%.

For instance, the separation grid 200 can have a first grid plate 210 and a second grid plate 220 in parallel relationship with one another. The first grid plate 210 can have a first grid pattern having a plurality of holes. The second grid plate 220 can have a second grid pattern having a plurality of holes. The first grid pattern can be the same as or different from the second grid pattern. Charged particles (e.g., ions) can recombine on the walls in their path through the holes of each grid plate 210, 220 in the separation grid 200. Neutral species (e.g., radicals) can flow relatively freely through the holes in the first grid plate 210 and the second grid plate 220.

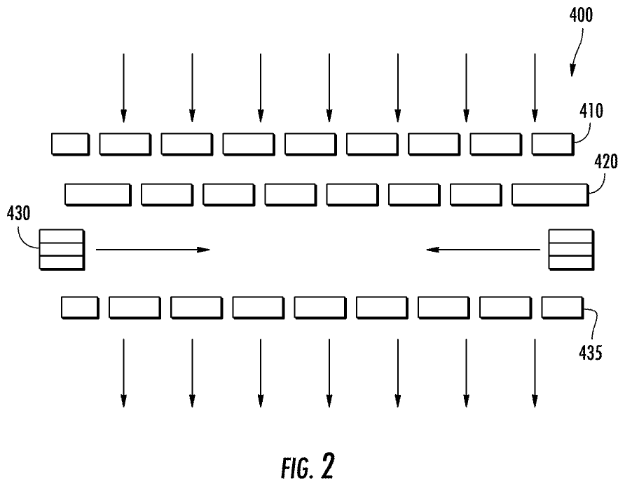

With reference to FIG. 2, subsequent to one or more grid plates (e.g., a first grid plate 410 and a second grid plate 420), one or more gas injection source(s) 430 (e.g., gas port) can be configured to admit a gas into the radicals. The radicals can then, in some embodiments, pass through a third grid plate 435 for exposure to the workpiece. The gas can be used for a variety of purposes. The gas 402 or other substance from the gas port 400 can be at a higher or lower temperature than the radicals coming from the plasma chamber 120 or can be the same temperature as the radicals from the plasma chamber 120. The gas can be used to adjust or correct uniformity, such as radical uniformity, within the plasma processing apparatus 500, by controlling the energy of the radicals passing through the separation grid 200. In some embodiments, the gas can be an inert gas, such as helium, nitrogen, and/or argon. In some aspects, methods may further include the step of admitting a non-process gas through one or more gas ports 430 at or below the separation grid 200 to adjust the energy of the radicals passing through the separation grid 200. The gas can be used to cool the radicals to control energy of the radicals passing through the separation grid. In some embodiments, a vaporized solvent can be injected into the separation grid via gas injection source(s) 430. In some embodiments, desired molecules (e.g., hydrocarbon molecules) can be injected into the radicals.

The post plasma gas injection illustrated in FIG. 2 is provided for example purposes. Those of ordinary skill in the art will understand that there are a variety of different configurations for implementing one or more gas ports in a separation grid for post plasma gas injection according to example embodiments of the present disclosure. The one or more gas ports can be arranged between any grid plates, can inject gas or molecules in any direction, and can be used to for multiple post plasma gas injection zones at the separation grid for uniformity control.

For instance, certain example embodiments can inject a gas or molecules at a separation grid in a center zone and an outer (peripheral) zone. More zones with gas injection at the separation grid can be provided without deviating from the scope of the present disclosure, such as three zones, four zones, five zones, six zones, etc. The zones can be partitioned in any manner, such as radially, azimuthally, or in any other manner. For instance, in one example, post plasma gas injection at the separation grid can be divided into a center zone and four azimuthal zones (e.g., quadrants) about the periphery of the separation grid.

In some embodiments, the pedestal 112 can be movable in a vertical direction V. For instance, the pedestal 112 can include a vertical lift that can be configured to adjust a distance between the pedestal 112 and the separation grid assembly 200. As one example, the pedestal 112 can be located in a first vertical position for processing using the remote plasma 502. The pedestal 112 can be in a second vertical position for processing using the direct plasma 504. The first vertical position can be closer to the separation grid assembly 200 relative to the second vertical position.

The example plasma processing apparatus 500 of FIG. 1 is operable to generate a first plasma 502 (e.g., a remote plasma) in the plasma chamber 120 and a second plasma 504 (e.g., a direct plasma) in the processing chamber 110. More particularly, the plasma processing apparatus 500 of FIG. 1 includes a CCP source comprising the electrode 128 and an electrode 510 (e.g., a bias electrode) in the pedestal 112. The electrode 510 can be directly coupled to an RF power generator terminal 514 (e.g., another terminal of the RF generator associated with the terminal 134). When the electrode 510 is energized with RF energy, a second plasma 504 can be generated from a mixture in the processing chamber 110 for direct exposure to the workpiece 114. The processing chamber 110 can include a gas exhaust port 516 for evacuating a gas from the processing chamber 110. The radicals or species used in the breakthrough process or etch process according to example aspects of the present disclosure can be generated using the first plasma 502 and/or the second plasma 504.

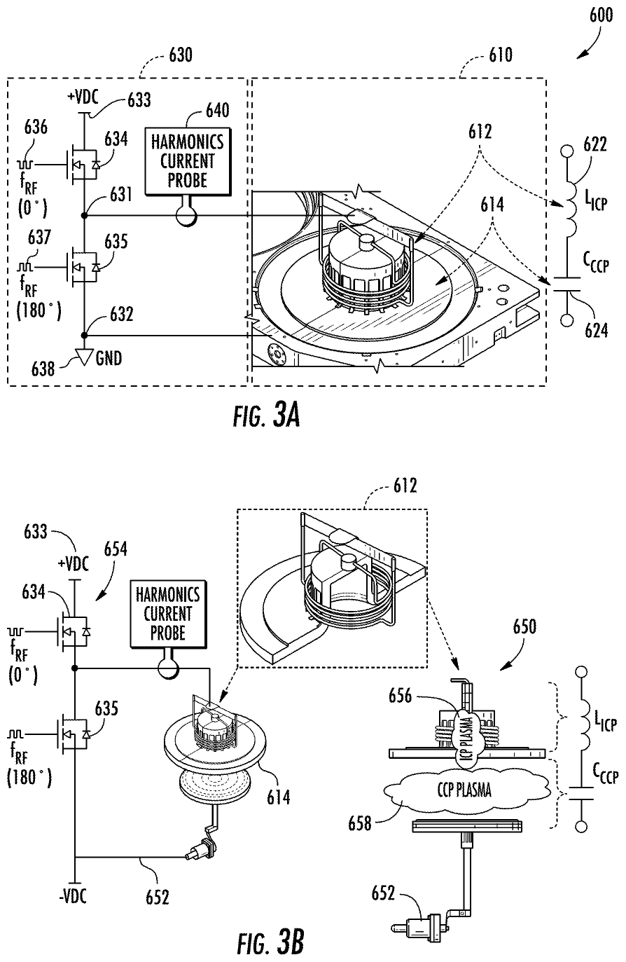

The RF generator terminals 134 and 514 can be electrically connected such that the equivalent lumped parameter circuit shown in FIGS. 3A and 3B approximately models the electrical behavior of the hybrid ICP-CCP plasma source. In one example, shown in FIG. 3B, the ICP source, CCP source, and an RF bias are all driven with the same RF generator.

Referring more particularly to FIG. 3A, an example hybrid plasma source 600 can include a resonant circuit 610 that includes an inductively coupled plasma (ICP) source 612 and a capacitively coupled plasma (CCP) source 614. The ICP source 612 provides an inductive component for resonant circuit 610 and CCP source 614 provides a capacitive component for resonant circuit 610. In some implementations, such as depicted in FIG. 3A, ICP source 612 is connected in series with CCP source 614. Although the present disclosure refers to a resonant circuit 610, it should be appreciated that a resonant circuit may also be referred to as an LC circuit, a tank circuit, a tuned circuit, or other circuit known to include an inductor (represented by letter L) and capacitor (represented by letter C) connected together. Resonant circuit schematic 620 provides a schematic representation of the source components within resonant circuit 610. More specifically, the ICP source 612 of resonant circuit 610 provides an inductance (L_{ICP}) 622 of resonant circuit schematic 620 and the CCP source 614 of resonant circuit 610 provides a capacitance (C_{CCP}) 624 of resonant circuit schematic 620.

Hybrid plasma source 600 can also include a controller 630. In some implementations, controller 630 can be configured to control operation of the ICP source 612 and the CCP source 614 such that the ICP source 612 and the CCP source 614 form a resonant circuit 610. More particularly, controller 630 can help ensure that the RF operating frequency of resonant circuit 610 is adjusted such that the resonant circuit 610 resonates at a desired excitation frequency. When operating conditions change in a plasma chamber employing hybrid plasma source 600, controller 630 can help automatically tune the operating frequency of resonant circuit 610 to track the chamber conditions in order to dynamically maintain series resonance so that RF power can be beneficially delivered to the plasma chamber at full capacity.

In one implementation of the disclosed technology, controller 630 of hybrid plasma source 600 can include a current sensor 640 coupled to the resonant circuit 610 and configured to measure harmonic components of the RF current generated by the resonant circuit 610. In some implementations, current sensor 640 can correspond to a VI probe. Current sensor 640 can be configured to measure only harmonic components of the RF current and not a fundamental component of the RF current generated by the resonant circuit 610. For example, an RF current generated by resonant circuit 610 can include a fundamental current component and a harmonic current component. The fundamental current component can correspond to the portion of RF current attributed to an excitation frequency, or resonant frequency, of the resonant circuit 610. The harmonic current component can be a sum or one or more currents respectively corresponding to one or more harmonics of the excitation frequency. Controller 630 in conjunction with current sensor 640 can be configured to directly measure the harmonic current component of the RF current generated by resonant circuit 610, and to control the excitation frequency by reducing a magnitude of the harmonic current below a target value. For example, aspects of the first RF clock signal 636, aspects of the second RF clock signal 637, or additional aspects of controller 630 (e.g., variable capacitors as described in later embodiments) can be selectively tuned to dynamically adjust the operating frequency of resonant circuit 610 for peak performance. Reducing or minimizing the harmonic current component can help to optimize series resonance and yield full capacitor performance for hybrid plasma source 600.

Referring still to FIG. 3A, controller 630 can include a matchless direct drive RF circuit that includes a first terminal 631 connected to the ICP source 612 and a second terminal 632 connected to the CCP source 614. RF power generated by resonant circuit 610 can be delivered to an RF source component 633 for a plasma processing apparatus. Controller 630 can include a first transistor 634 and second transistor 635 that can respectively correspond, for example, to field effect transistors such as MOSFETS. First transistor 634 can be provided between first terminal 631 and RF source component 633, while a second transistor 635 can be provided between first terminal 631 and second terminal 632, which is connected to ground 638. First terminal 631 is positioned between a drain terminal of second transistor 635 and a source terminal of first transistor 634, while second terminal 632 is connected to a source terminal of second transistor 635. First transistor 634 can be configured to receive a first RF signal 636 at its gate terminal, while second transistor 635 can be configured to receive a second RF signal 637 at its gate terminal. In some implementations, first RF signal 636 and second RF signal 637 are pulsed RF clock signals. In some implementations, first RF signal 636 and second RF signal 637 are square wave signals characterized by a pulsing frequency of f_{RF}. In some implementations, first RF signal 636 is shifted in phase relative to second RF signal 637. For instance, first RF signal 636 can be shifted from second RF signal 637 by about 180 degrees, thus being characterized by substantially opposite signal phase. A drain terminal of first transistor 634 can deliver power to RF source 633.

Referring more particularly, to FIG. 3B, a hybrid plasma source 650 includes similar components to hybrid plasma source 600 of FIG. 3A. However, in hybrid plasma source 650, ICP source 612, CCP source 614 and an RF bias component 652 are all driven by the same single matchless direct drive circuit 654. In such instance, instead of the drain terminal of second transistor 635 being connected to ground, the drain terminal of second transistor 635 is connected to RF bias component 652. As such +V_{DC} in FIG. 3B provides power to RF source component 633, while −V_{DC} in FIG. 3B provides power to RF bias component 652.

According to another aspect of the disclosed technology, FIG. 3B also depicts how the ICP source 612 and CCP source 614 are both plasma generating elements that collectively form a hybrid plasma source. More particularly, as shown in FIG. 3B, ICP source 612 generates a first plasma portion 656 in a center region, while CCP source 614 generates a second plasma portion 658 in an outer region (e.g., of a plasma processing apparatus such as depicted in FIG. 1). The relative contributions of first plasma portion 656 from ICP source 612 and second plasma portion 658 from CCP source 614 as depicted in FIG. 3B can be understood to equally apply to other hybrid plasma source embodiments illustrated and discussed herein.

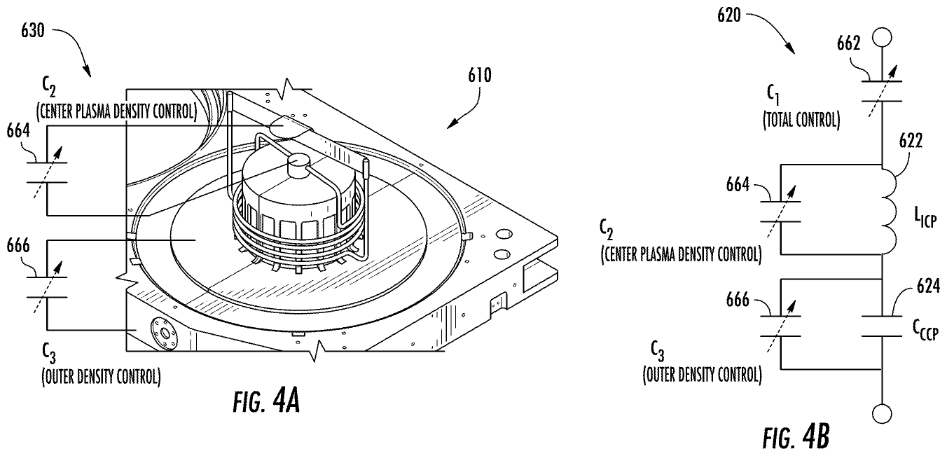

Referring now to FIGS. 4A & 4B, in some embodiments, a controller (e.g., controller 630) connected to resonant circuit 610 of a hybrid plasma source can include additional circuit elements (e.g., variable capacitors) to provide for tuning of the overall resonant frequency (e.g., by adjusting capacitance C1) and/or the relative power allocation of the ICP and CCP (e.g., by adjusting the capacitances C2 and C3, respectively). In this manner, the uniformity between center plasma density (e.g., as affected by the ICP source) and the outer plasma density (e.g., as affected by the CCP source) can be tuned.

With more particular reference to FIGS. 4A & 4B, controller 630 can include one or more additional circuit elements coupled to hybrid plasma source 600 including ICP source 612 and CCP source 614. In some implementations, a first circuit element C1 (e.g., variable capacitor 662) can be connected in series with ICP source 612 and CCP source 614 (represented in FIG. 4B as L_{ICP} 622 and C_{CCP} 624). Variable capacitor 662 can be configured to adjust an operating frequency of the resonant circuit 610 (e.g., in response to harmonic current measurements obtained by current sensor 640). In some implementations, controller 630 can include a second circuit element C2 coupled to ICP source 612 and a third circuit element C3 coupled to the CCP source 614. For instance, second circuit element C2 can correspond to a first first power density circuit element (e.g., variable capacitor 664 connected in parallel with L_{ICP} 622 from ICP source 612). Similarly, third circuit element C3 can correspond to a second power density circuit element (e.g., variable capacitor 666 connected in parallel with C_{CCP} 624 from CCP source 614). Variable capacitor 664 can be configured to adjust a density of center plasma (e.g., first plasma portion 656 in FIG. 3B) and corresponding power allocated from the ICP source 612 in the hybrid plasma source 600, while variable capacitor 666 can be configured to adjust a density of outer plasma (e.g., second plasma portion 658 in FIG. 3B) and corresponding power allocated from the CCP source 614 in the hybrid plasma source 600.

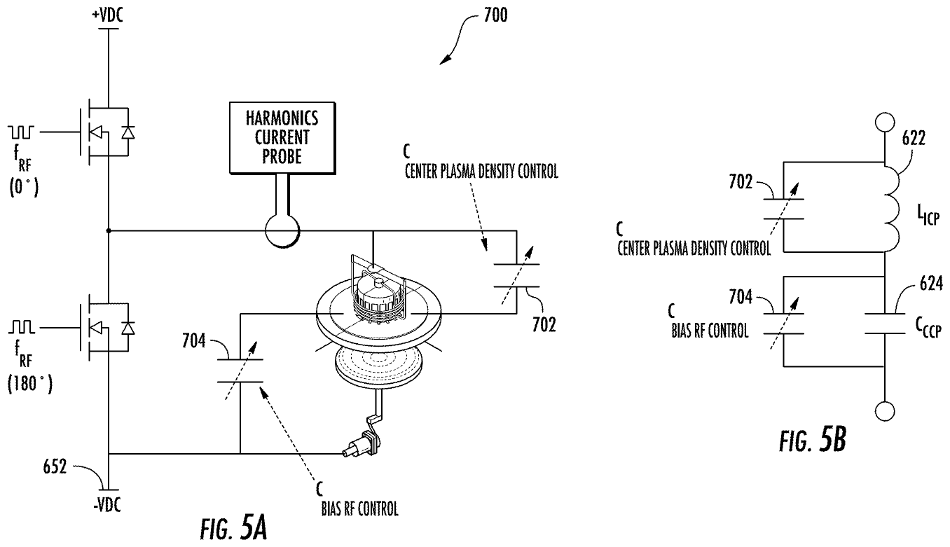

Another example of a controller 630 including additional circuit elements for tuning of RF bias control in a hybrid plasma source is depicted in FIGS. 5A and 5B. In FIG. 5A, a hybrid plasma source 700 is configured with a controller that includes a variable capacitor 702 and a variable capacitor 704. Variable capacitor 702 can be connected in parallel with ICP source 612 (depicted as L_{ICP} 622 in FIG. 5B), while variable capacitor 704 can be connected in parallel with CCP source (depicted by C_{CCP} 624 in FIG. 5B). Variable capacitor 704 can be a bias capacitor configured to adjust one or more parameters of the power delivered to the RF bias component 652. Bias RF control provided by variable capacitor 704 can be configured to not only control the bias RF voltage and thus average ion energy, but also to control the bias frequency accordingly that in return adjusts the ion energy distribution frequency (IEDF) at the same time. In the hybrid plasma source 700 of FIGS. 5A and 5B, no variable capacitor in series with ICP source 612 and CCP source 614 is necessary.

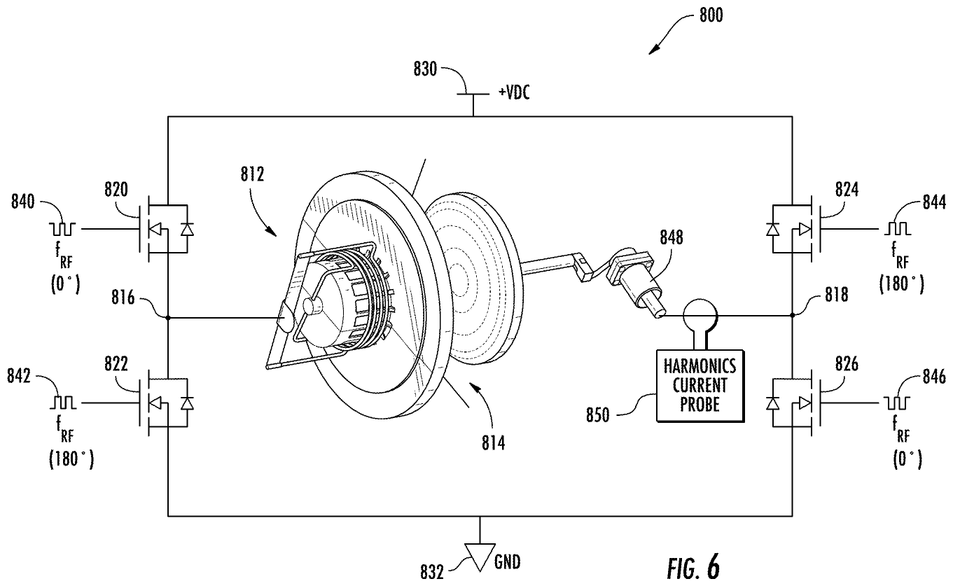

Referring now to FIG. 6, a hybrid plasma source 800 includes a controller having a full H-bridge switching configuration for providing pulsed RF power from a resonant circuit that includes an ICP source 812 and a CCP source 814. It should be appreciated that the previously discussed designs of FIGS. 3A-3B, 4A-4B, and 5A-5B included a half-bridge switching configuration for providing pulsed RF power from the resonant circuit. However, aspects depicted in and discussed with reference to the half-bridge implementations of FIGS. 3A-3B, 4A-4B, and 5A-5B can equally apply to the full-bridge implementation of FIG. 6. More particularly, aspects of ICP source 612 and CCP source 614 as previously discussed can be incorporated with the ICP source 812 and CCP source 814 of FIG. 6.

Referring still to FIG. 6, hybrid plasma source 800 can include a first terminal 816 coupled to ICP source 812 and a second terminal 818 coupled to CCP source 814. A first side of the full-bridge controller design of FIG. 6 is embodied at least in part by a first transistor 820 and second transistor 822, while a second side of the full-bridge controller design is embodied at least in part by a third transistor 824 and fourth transistor 826. One or more of the first transistor 820, second transistor 822, third transistor 824, and fourth transistor 826 can include a field-effect transistor, such as but not limited to a MOSFET. First transistor 820 can be provided between first terminal 816 and RF source component 830, while second transistor 822 can be provided between first terminal 816 and a ground 832. First terminal 816 can be positioned between a drain terminal of second transistor 822 and a source terminal of first transistor 820, while a source terminal of second transistor 822 can be connected to ground 832. Third transistor 824 can be provided between second terminal 818 and RF source component 830, while fourth transistor 826 can be provided between second terminal 818 and a ground 832. Second terminal 818 can be positioned between a drain terminal of fourth transistor 826 and a source terminal of third transistor 824, while a source terminal of fourth transistor 826 can be connected to ground 832.

Referring still to FIG. 6, first transistor 820 can be configured to receive a first RF signal 840 at its gate terminal, second transistor 822 can be configured to receive a second RF signal 842 at its gate terminal, third transistor 824 can be configured to receive a third RF signal 844 at its gate terminal, and fourth transistor 826 can be configured to receive a fourth RF signal 846 at its gate terminal. In some implementations, first RF signal 840, second RF signal 842, third RF signal 844, and fourth RF signal 846 are pulsed RF clock signals. In some implementations, first RF signal 840, second RF signal 842, third RF signal 844, and fourth RF signal 846 are square wave signals characterized by a pulsing frequency of f_{RF}. In some implementations, a phase of first RF signal 840 is shifted relative to a phase of second RF signal 842, and similarly, a phase of third RF signal 844 is shifted relative to a phase of fourth RF signal 846. For instance, first RF signal 840 can be shifted from second RF signal 842 by about 180 degrees, thus being characterized by substantially opposite signal phase. Third RF signal 844 can be shifted from fourth RF signal 846 by about 180 degrees, thus being characterized by substantially opposite signal phase.

An RF generator in accordance with the disclosed hybrid plasma sources can be operable at various frequencies. In some embodiments, for example, the RF generator can energize the induction coil 130 and the electrode 510 with RF power at frequency of about 13.56 MHz. In certain example embodiments, the RF generator may be operable to energize the electrode 510 and/or the induction coil 130 with RF power at frequencies in a range between about 400 KHz and about 60 MHz. In addition, an RF generator in accordance with the disclosed hybrid plasma sources can be readily implemented for a number of different RF pulsing schemes with almost unlimited levels of RF pulsing.

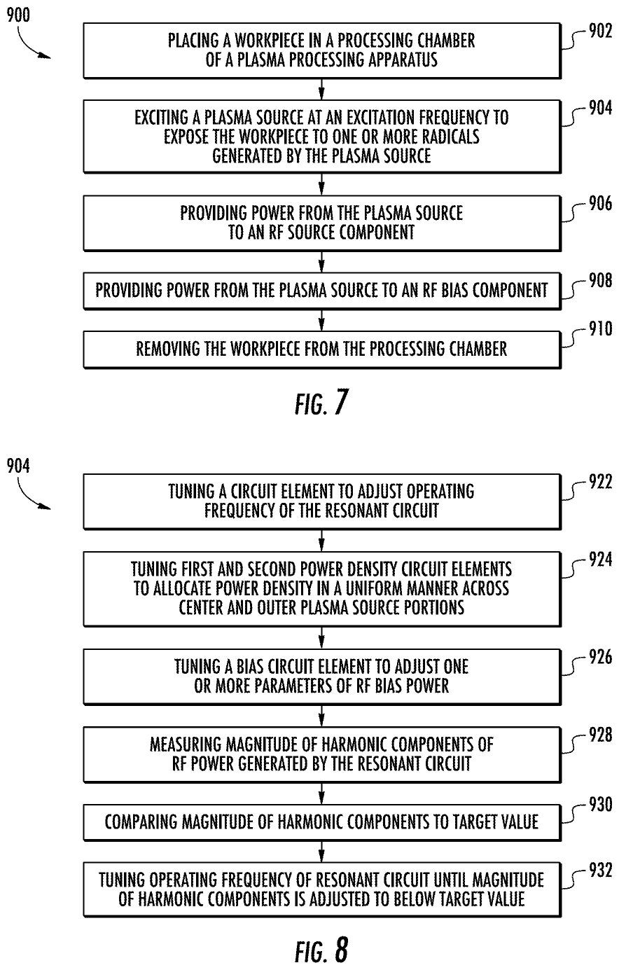

Referring now to FIG. 7, an example method 900 for processing a workpiece is depicted.

In some implementations, at 902, method 900 can include placing a workpiece (e.g., workpiece 114 of FIG. 1) in a processing chamber (e.g., processing chamber 110 of FIG. 1) of a plasma processing apparatus (e.g., plasma processing apparatus 500 of FIG. 1). The processing chamber in which the workpiece is placed at 902 can be separated from a plasma chamber (e.g., plasma chamber 120 of FIG. 1). For example, a processing chamber and plasma chamber can be separated by a separation grid assembly (e.g., separation grid assembly 200 of FIG. 2). For instance, the method can include placing a workpiece 114 onto workpiece support 112 in the processing chamber 110, as depicted in FIG. 1.

In some implementations, at 904, method 900 can include exciting a plasma source (e.g., one or more of the hybrid plasma sources 600, 650, 700, 800 described herein) at an excitation frequency to expose the workpiece (e.g., workpiece 114 of FIG. 1) to one or more radicals generated by the plasma source. In some implementations, the plasma source excited at 904 can include a resonant circuit that includes an inductively coupled plasma source and a capacitively coupled plasma source. In some implementations, the resonant circuit is configured to operate in series resonance at the excitation frequency. In some implementations, the excitation frequency of the hybrid plasma source can be controlled by reducing a harmonic current below a target value, wherein the harmonic current is a sum of one or more currents respectively corresponding to one or more harmonics of the excitation frequency. Additional details regarding steps for tuning the excitation frequency or resonant frequency of the hybrid plasma source is depicted in FIG. 10.

In some implementations, at 906, method 900 can include providing power from the plasma source to an RF source component, such as depicted in FIGS. 3A and 6. In some implementations, at 908, method 900 can include additionally providing power from the plasma source to an RF bias component, such as depicted in FIGS. 3B, 5A and 5B.

In some implementations, at 910, method 900 can include removing the workpiece from the processing chamber. For instance, the workpiece 114 can be removed from workpiece support 112 in the processing chamber 110, as depicted in FIG. 1. The plasma processing apparatus can then be conditioned for future processing of additional workpieces.

Referring now to FIG. 8, more detailed example aspects associated with exciting a plasma source at an excitation frequency at 904 as depicted in FIG. 7 are presented. It should be appreciated that the aspects depicted in FIG. 8 can be selectively incorporated, meaning that some or all of the steps shown can be implemented. In addition, the order in which various steps, features or relates aspects are implemented can vary.

More particularly, in some implementations, exciting a plasma source at 904 can include tuning at 922 a circuit element (e.g., a variable capacitor connected in series with the inductively coupled plasma source and a capacitively coupled plasma source) to adjust the operating frequency of the resonant circuit. In some implementations, exciting a plasma source at 904 can include tuning at 924 a first power density circuit element (e.g., a parallel-connected variable capacitor) coupled to the inductively coupled plasma source and a second power density circuit element (e.g., a parallel-connected variable capacitor) coupled to the capacitively coupled plasma source to allocate uniformity in power across both a center portion and an outer portion of the plasma source. In some implementations, exciting a plasma source at 904 can include tuning at 926 a bias circuit element (e.g., a variable capacitor connected in parallel with an RF bias) to adjust one or more parameters of the power delivered to the RF bias component. In some implementations, such as when exciting a plasma source at 904 includes reducing a harmonic current below a target value, steps can be included for measuring at 928 a magnitude of harmonic components of an RF current generated by the resonant circuit (e.g., by a current sensor or probe as described herein), comparing at 930 the magnitude of harmonic components of the RF current generated by the resonant circuit to the target value, and tuning at 932 an operating frequency of the resonant circuit until the magnitude of the harmonic components of the RF current generated by the resonant circuit is reduced to below the target value.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A hybrid plasma source, comprising:
an inductively coupled plasma source;
a capacitively coupled plasma source; and
a controller configured to control operation of the inductively coupled plasma source and the capacitively coupled plasma source such that the inductively coupled plasma source and the capacitively coupled plasma source form a resonant circuit.

2. The hybrid plasma source of claim 1, the controller comprising:
a variable capacitor connected in series with the inductively coupled plasma source and the capacitively coupled plasma source, the variable capacitor configured to adjust an operating frequency of the resonant circuit.

3. The hybrid plasma source of claim 1, the controller comprising:
a first power density circuit element coupled to the inductively coupled plasma source and configured to adjust a density of power allocated from the inductively coupled plasma source in the hybrid plasma source; and
a second power density circuit element coupled to the capacitively coupled plasma source and configured to adjust a density of power allocated from the capacitively coupled plasma source in the hybrid plasma source.

4. The hybrid plasma source of claim 3, wherein:
the first power density circuit element comprises a first capacitor connected in parallel with the inductively coupled plasma source; and
the second power density circuit element comprises a second capacitor connected in parallel with the capacitively coupled plasma source.

5. The hybrid plasma source of claim 2, the controller comprising:
a current sensor coupled to the resonant circuit and configured to measure harmonic components of an RF current generated by the resonant circuit.

6. The hybrid plasma source of claim 5, wherein the controller is configured to adjust the variable capacitor such that a magnitude of harmonic components of the RF current generated by the resonant circuit are reduced.

7. The hybrid plasma source of claim 1, wherein the resonant circuit is configured to deliver power to an RF source component for a plasma processing apparatus.

8. The hybrid plasma source of claim 7, wherein the resonant circuit is further configured to deliver power to an RF bias component for a plasma processing apparatus.

9. The hybrid plasma source of claim 8, the controller comprising a bias capacitor configured to adjust one or more parameters of the power delivered to the RF bias component.

10. The hybrid plasma source of claim 1, wherein the controller comprises a half-bridge switching configuration for providing pulsed RF power from the resonant circuit.

11. The hybrid plasma source of claim 1, wherein the controller comprises a full H-bridge switching configuration for providing pulsed RF power from the resonant circuit.

12. A method for processing a workpiece, the method comprising:
exciting a plasma source at an excitation frequency to expose the workpiece to one or more radicals generated by the plasma source, wherein the excitation frequency is controlled by reducing a harmonic current below a target value, wherein the harmonic current is a sum of one or more currents respectively corresponding to one or more harmonics of the excitation frequency.

13. The method for processing a workpiece of claim 12, comprising:
providing power from the plasma source to an RF source component; and
providing power from the plasma source to an RF bias component.

14. The method for processing a workpiece of claim 12, wherein the plasma source comprises a resonant circuit that includes an inductively coupled plasma source and a capacitively coupled plasma source.

15. The method for processing a workpiece of claim 14, wherein the resonant circuit is configured to operate in series resonance at the excitation frequency.

16. The method for processing a workpiece of claim 14, comprising:
tuning a variable capacitor connected in series with the inductively coupled plasma source and a capacitively coupled plasma source to adjust an operating frequency of the resonant circuit.

17. The method for processing a workpiece of claim 14, comprising:
tuning a first power density circuit element coupled to the inductively coupled plasma source and a second power density circuit element coupled to the capacitively coupled plasma source to allocate uniformity in power across both a center portion and an outer portion of the plasma source.

18. The method for processing a workpiece of claim 14, wherein reducing a harmonic current below a target value comprises:
measuring a magnitude of harmonic components of an RF current generated by the resonant circuit;
comparing the magnitude of harmonic components of the RF current generated by the resonant circuit to the target value; and
tuning an operating frequency of the resonant circuit until the magnitude of the harmonic components of the RF current generated by the resonant circuit is reduced to below the target value.

19. An apparatus for processing a workpiece, the apparatus comprising:
a processing chamber having an interior space operable to receive a process gas;
a substrate holder in the interior space of the processing chamber operable to hold a substrate;
a hybrid plasma source comprising a resonant circuit that includes an inductively coupled plasma source and a capacitively coupled plasma source, the resonant circuit configured for operation at an excitation frequency; and
a controller configured to adjust the excitation frequency by reducing a harmonic current below a target value, wherein the harmonic current is a sum of one or more currents respectively corresponding to one or more harmonics of the excitation frequency.

20. The apparatus for processing a workpiece of claim 19, wherein the controller is configured to provide pulsed RF power to at least one an RF source component or an RF bias component.
